(19) United States
(12) Patent Application Publication
(10) Pub. No.: US 2011/0073932 A1
(43) Pub. Date: Mar. 31, 2011

(54) NON VOLATILE SEMICONDUCTOR MEMORY DEVICE

(75) Inventors: Kazuhiro Shimizu, Yokkaichi-Shi (JP); Hideto Horii, Yokohama-Shi (JP)

(73) Assignee: KABUSHIKI KAISHA TOSHIBA, Tokyo (JP)

(21) Appl. No.: 12/724,710

(22) Filed: Mar. 16, 2010

(30) Foreign Application Priority Data
Sep. 25, 2009 (JP) 2009-221281

(51) Int. Cl. H01L 29/792

(52) U.S. Cl. 257/324; 257/E29.309

(57) ABSTRACT

A non volatile semiconductor memory device includes: a semiconductor substrate comprising element regions; gate structures each comprising a first gate insulation film, a charge storage layer, a second gate insulation film, and a control gate; element isolation insulation films defining the element regions and electrically isolating the element regions; impurity diffusion layers in the element regions; a third gate insulation film of a first insulation material located between the gate structures; and a fourth gate insulation film of a second insulation material which is different from the first insulation material configured to be in contact with side walls of the gate structures. A bottom face of the fourth gate insulation film is located so as to be remote from a surface of the semiconductor substrate by a distance equal to at least half of a height of the charge storage layer.

### CROSS REFERENCE TO RELATED APPLICATION

This application claims benefit of priority under 35 USC §119 to Japanese Patent Application No.2009-221281, filed on Sep. 25, 2009, the contents of which are incorporate by reference herein.

### BACKGROUND

A non volatile semiconductor memory device includes a charge storage layer (floating gate) formed over a substrate via a first gate insulation film, and a control gate formed over the charge storage layer via a second gate insulation film. When writing data, electrons are injected into the charge storage layer by, for example, applying a positive voltage to the control gate and a drain region, and grounding the substrate and a source region. As a result, a threshold value of the control gate is changed to make a distinction between “0” and “1.” As a representative of large-capacity high-density non volatile semiconductor memories, there is a NAND EEPROM having a self-aligned Shallow Trench Isolation (STI) memory structure which can be integrated with the highest density.

If the element region width, element isolation width, gate width or the inter-gate space is reduced for attaining a higher density and a larger capacity in the conventional self-aligned STI cell structure, however, then the breakdown voltage between adjacent gates is deteriorated and the parasitic capacitance increases (see, for example, International Publication WO 2005/081318 A1). In addition, memory cell characteristics are deteriorated and threshold distribution is aggravated because cell channel current deterioration is caused by electron trapping on a surface of an n-type diffusion layer. The conventional self-aligned STI cell structure has such problems.

### SUMMARY

According to a first aspect of the present invention, there is provided a non volatile semiconductor memory device comprising:

a semiconductor substrate which comprises a plurality of element regions extending in a first direction;

a plurality of gate structures configured to extend in a second direction intersecting the first direction, each of the gate structures comprising a charge storage layer provided over the semiconductor substrate via a first gate insulation film, a second gate insulation film on the charge storage layer, and a control gate on the second gate insulation film;

a plurality of element isolation insulation films provided selectively on a surface of the semiconductor substrate to define the element regions and electrically isolate the element regions;

a plurality of impurity diffusion layers provided in the element regions so as to sandwich a surface layer of the semiconductor substrate located right under the gate structures therebetween;

a third gate insulation film of a first insulation material located between the gate structures; and

a fourth gate insulation film of a second insulation material which is different from the first insulation material configured to be in contact with side walls of the gate structures,

wherein a bottom face of the fourth gate insulation film is located so as to be remote from a surface of the semiconductor substrate by a distance equal to at least half of a height of the charge storage layer.

According to a second aspect of the present invention, there is provided a non volatile semiconductor memory device comprising:

a semiconductor substrate which comprises a plurality of element regions extending in a first direction;

a plurality of gate structures configured to extend in a second direction intersecting the first direction, each of the gate structures comprising a charge storage layer provided over the semiconductor substrate via a first gate insulation film, a second gate insulation film on the charge storage layer, and a control gate on the second gate insulation film;

a plurality of element isolation insulation films provided selectively on a surface of the semiconductor substrate to define the element regions and electrically isolate the element regions;

a plurality of impurity diffusion layers provided in the element regions so as to sandwich a surface layer of the semiconductor substrate located right under the gate structures therebetween;

a third gate insulation film of a first insulation material located between the gate structures; and

a fourth gate insulation film of a second insulation material having a permittivity which is lower than that of the first insulation material in contact with side walls of the gate structure and the semiconductor substrate between the gate structures.

According to a third aspect of the present invention, there is provided a non volatile semiconductor memory device comprising:

a semiconductor substrate which comprises a plurality of element regions extending in a first direction;

a plurality of gate structures configured to extend in a second direction intersecting the first direction, each of the gate structures comprising a charge storage layer provided over the semiconductor substrate via a first gate insulation film, a second gate insulation film on the charge storage layer, and a control gate on the second gate insulation film;

a plurality of element isolation insulation films provided selectively on a surface of the semiconductor substrate to define the element regions and electrically isolate the element regions;

a plurality of impurity diffusion layers provided in the element regions so as to sandwich a surface layer of the semiconductor substrate located right under the gate structures therebetween;

a third gate insulation film of a first insulation material located between the gate structures; and

a fourth gate insulation film of a second insulation material which is different from the first insulation material in contact with side walls of the gate structure; and

a fifth gate insulation film of a third insulation material which is different from the first insulation material, located in the third gate insulation film,

wherein the second and third insulation materials are higher in permittivity than the first insulation material.

### BRIEF DESCRIPTION OF THE DRAWINGS

In accompanying drawings,

FIG. 1 is a diagram schematically showing a solving method which alleviates an inter-gate electric field and suppresses insulation deterioration;

FIG. 2 is a graph showing an example of a relation between a film thickness of an insulation material of an inter-gate insulation film which is in contact with a gate structure, and a voltage which can be applied to the control gate at the time of writing;

FIG. 3 is a top view schematically showing a memory structure of a non volatile semiconductor memory device according to a first embodiment of the present invention;

FIGS. 4A to 4D are sectional views schematically showing a memory structure of a non volatile semiconductor memory device according to a first embodiment of the present invention;

FIGS. 5A to 5D are sectional views showing an example of a non volatile semiconductor memory device according to a first comparative example;

FIGS. 6A to 6D are sectional views showing an example of a non volatile semiconductor memory device according to a second comparative example;

FIGS. 7A to 7D are sectional views schematically showing a memory structure of a non volatile semiconductor memory device according to a second embodiment of the present invention;

FIGS. 8A to 8D are sectional views schematically showing a memory structure of a non volatile semiconductor memory device according to a third embodiment of the present invention;

FIGS. 9A to 9D are sectional views schematically showing a memory structure of a non volatile semiconductor memory device according to a fourth embodiment of the present invention;

FIGS. 10A to 10D are sectional views schematically showing a memory structure of a non volatile semiconductor memory device according to a fifth embodiment of the present invention;

FIGS. 11A to 11D are sectional views schematically showing a memory structure of a non volatile semiconductor memory device according to a sixth embodiment of the present invention; and

FIG. 12 is a diagram schematically showing a solving method which alleviates an inter-gate electric field and suppresses insulation deterioration in the memory structures shown in FIGS. 11A-11D.

### DESCRIPTION

Hereafter, some embodiments of the present invention will be described in detail with reference to the drawings. In the drawings, the same part is denoted by the same character, and duplicated description is made only in the case where it is needed.

### (1) Method For Suppressing Insulation Deterioration

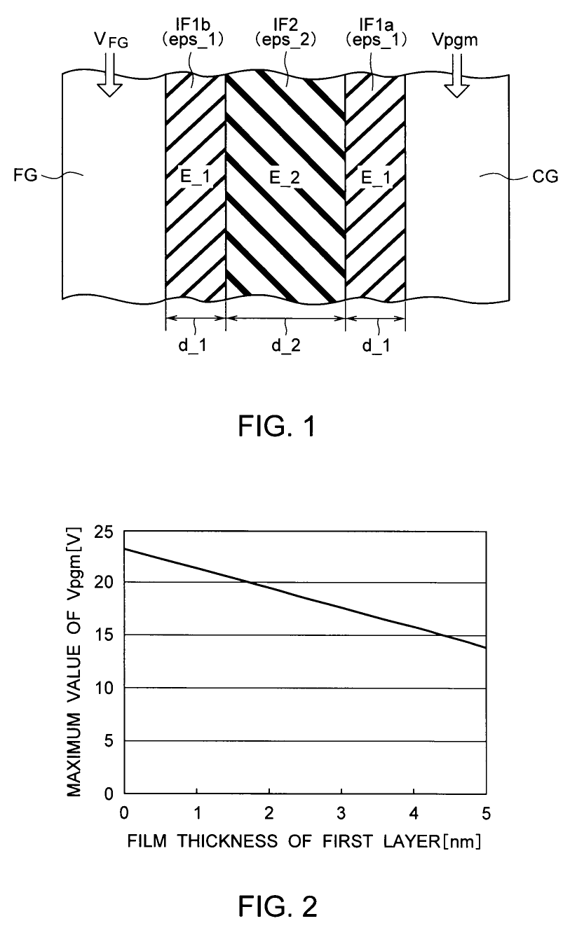

FIG. 1 is a diagram schematically showing a solving method which alleviates an inter-gate electric field and suppresses insulation deterioration. FIG. 1 shows electric field relations in a cell structure of an example of a NAND EEPROM in a self-aligned STI memory structure. A stacked gate structure in the form of a parallel plate is disposed on the left and right sides in FIG. 1. Inter-gate insulation films IF1a, IF2 and IF1b having a three-layer structure and composed of two kinds of insulation materials, for example, are disposed between control gates CG respectively formed on charge storage layers. In the cell structure in FIG. 1, for example, the control gate CG supplied with a write voltage (Vpgm) is shown on the right side in the diagram whereas a charge storage layer FG disposed under a control gate CG and supplied with a write preventing intermediate voltage (Vpass) is shown on the left side in the diagram. The inter-gate insulation films IF1a and IF1b which are in contact with the control gate CG and the charge storage layer FG disposed under the control gates CG are formed of an insulation material of the same kind (referred to as “insulation material A”). The relative permittivity of the insulation material A is denoted by eps_{—}1, its film thickness is denoted by d_{—}1, and the electric field strength applied to the material A is denoted by E_{—}1. The inter-gate insulation film IF2 inserted between the inter-gate insulation films IF1a and IF1b is formed of an insulation material B which is different from the insulation material A. The relative permittivity of the insulation material B is denoted by eps_{—}2, its film thickness is denoted by d_{—}2, and the electric field strength applied to the material B is denoted by E_{—}2.

The electric field strength E_i (i=1, 2) in each insulation film can be represented as

E_{—}=K*V/eps_{—}i [Expression] 1

### Where

K=1/(2*d_{—}1/eps_{—}1+d_{—}2/eps_{—}2) [Expression] 2

In general, a current flowing through a comparatively thick insulation film is expressed in the Fowler-Nordheim type or the Poole-Frankel type. Therefore, it is important to reduce the electric field applied to the insulation film. In other words, since it is considered that the leak current can be suppressed if the electric field in the electron emitting part is alleviated, it is necessary to satisfy the relation E_{—}1<E_{—}2 in the structure shown in FIG. 1. From Expression 1, the condition for satisfying the relation E_{—}1<E_{—}2 becomes eps_{—}1>eps_{—}2. By the way, since the potential relations between adjacent cells are interchanged concurrently with writing, a symmetric structure is obtained in the actual memory cell structure.

FIG. 2 is a graph showing an example of the relation between the film thickness of the insulation material A and a voltage which can be applied to the control gate at the time of writing. The distance between adjacent cells is set equal to 10 nm, and a potential VFG on the charge storage layer FG under the control gate to which the write preventing intermediate voltage Vpass is applied is set equal to 4 V. Furthermore, it is assumed that the dielectric strength is 10 MV/cm for convenience.

In the case where, for example, a silicon nitride film (eps_{—}1 =7.5 and d_{—}1=2 nm) is used as the insulation film IF1a of the first layer and, for example, a silicon oxide film (eps_{—}2=3.9 and d_{—}2=6 nm) is used as the insulation film IF2 of the second layer, the voltage which can be applied to the silicon nitride film of the first layer becomes 19.5 V at a maximum. It is understood that the voltage which can be applied becomes high due to the electric field alleviation effect if the film thickness of the silicon nitride film of the first layer is decreased under this setting. If the silicon nitride film of the first layer having a high permittivity is made thick, then an adverse effect is also brought about in that the spread of the threshold distribution caused by interference between adjacent cells is aggravated and precise threshold control becomes difficult, because parasitic capacitance between charge storage layers of adjacent cells becomes high. Therefore, it becomes necessary to contrive to decrease the film thickness of the silicon nitride film of the first layer. Specifically, it is desirable to set the film thickness of the silicon nitride film of the first layer equal to or less the film thickness of the inter-gate insulation film between the control gate and the charge storage layer in the memory cell.

### (2) First Embodiment

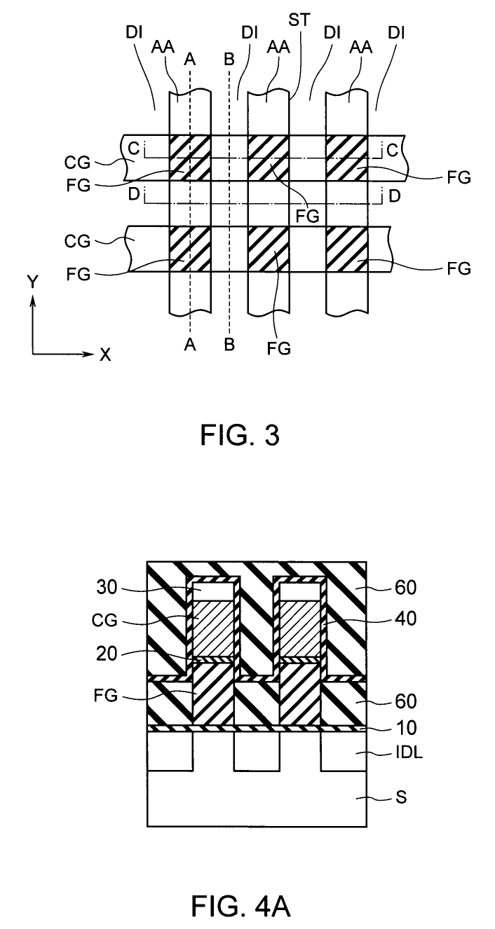

A first embodiment of the present invention will be described with reference to FIGS. 3 to 6D.

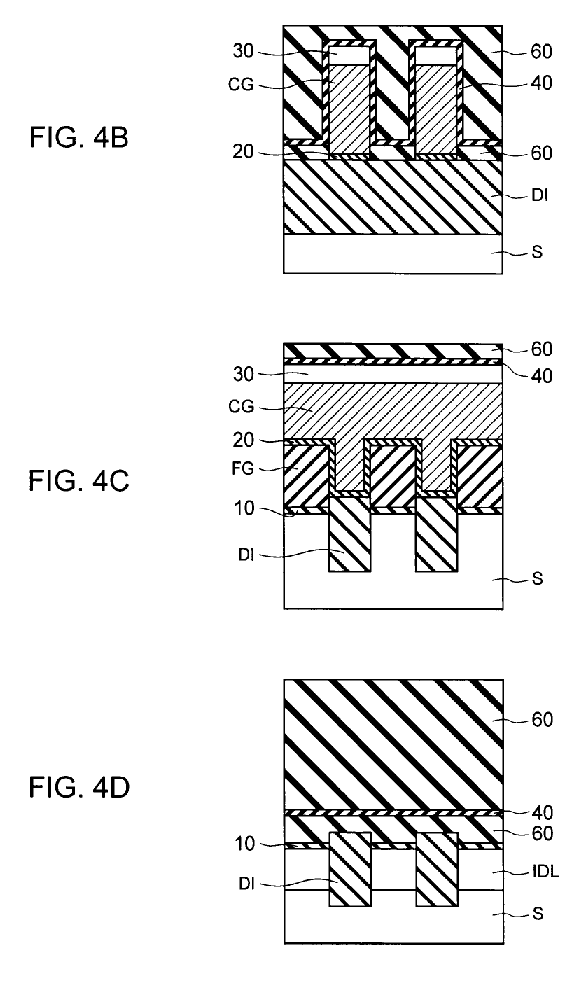

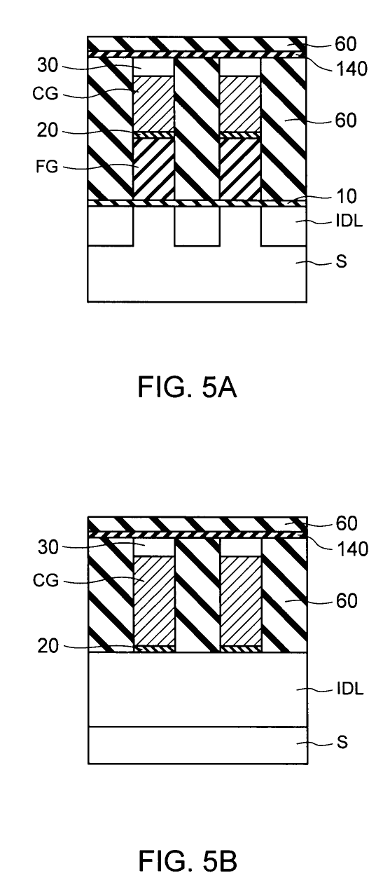

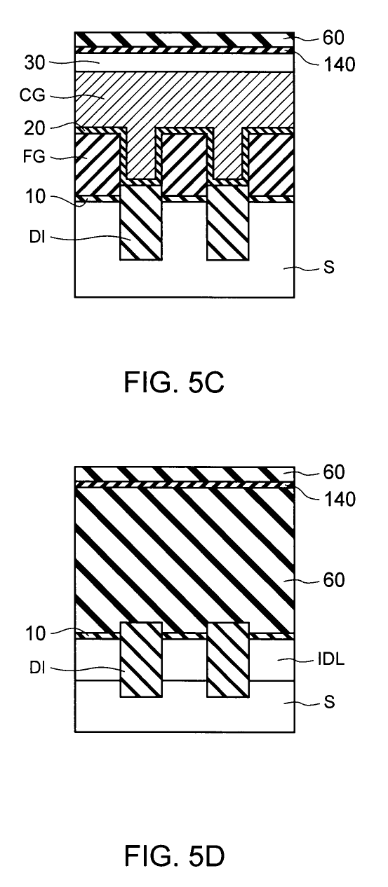

FIG. 3 is a top view schematically showing a memory structure of a non volatile semiconductor memory device according to the present embodiment. FIGS. 4A to 4D are respective schematic sectional views. In FIG. 3, only a layout of a region of an element isolation insulation film DI, an element region AA, the charge storage layer FG and the control gate CG are shown. FIGS. 4A to 4D are sectional views obtained by viewing the memory structure along an A-A cut line, a B-B cut line, a C-C cut line and a D-D cut line shown in FIG. 3, respectively. Relations between the cut lines and the sectional views are true of FIGS. 5A to 11D as well.

First, a memory structure of the non volatile semiconductor memory device according to the present embodiment will be described with reference to FIGS. 3 to 4D.

An element isolation trench ST (Shallow Trench) is formed in an element isolation region on the surface of a silicon substrate S. An insulation material for element isolation, for example, a silicon dioxide material is buried within the trench ST to form the element isolation insulation film DI and define the element region AA. A thin tunnel insulation film 10 through which a tunnel current can flow is formed on the entire element region AA which is isolated from the other elements by the element isolation insulation film DI. A charge storage layer FG is formed in a region in the element region AA on the tunnel insulation film 10 which intersects a gate structure. The charge storage layer FG has side end parts aligned with boundaries of the element isolation region. Parts of the element isolation insulation films DI are in contact with the charge storage layers FG (see FIG. 4C). The top face of the charge storage layer FG faces the control gate CG via an inter-gate insulation film 20. It is contrived to increase the capacitance between the charge storage layer FG and the control gate CG in this way. A stacked gate cap material 30 is formed on the top face of the control gate CG. The stacked gate cap material 30, the control gate CG, the inter-gate insulation film 20 and the charge storage layer FG constitute a stacked gate structure. The control gate CG and the charge storage layer FG are subjected to vertical processing in a self-aligned manner to align in side walls. In the surface layer of the semiconductor substrate S, n-type impurity diffusion layers IDL are formed so as to sandwich the surface layer right under the control gate CG therebetween. The n-type impurity diffusion layer IDL becomes a source-drain region with the surface layer disposed right under the control gate CG serving as a channel region.

As shown in FIG. 4A, a silicon nitride insulation film 40 is formed in contact with the stacked gate structure as if to cover the individual stacked gate structure. As a result, it is possible to prevent impurities such as hydrogen and metal elements from entering from the outside. In addition, a silicon oxide insulation material is buried between adjacent control gates CG and charge storage layers FG to form a silicon oxide insulation film 60. As a result, parts between adjacent control gates CG and parts between adjacent charge storage layers FG are electrically isolated from other elements.

In the present embodiment, a Y direction shown in FIG. 3 corresponds to, for example, a first direction, and an X direction shown in FIG. 3 corresponds to, for example, a second direction. The tunnel insulation film 10 corresponds to, for example, a first gate insulation film and the inter-gate insulation film 20 corresponds to, for example, a second gate insulation film. In addition, silicon oxide and silicon nitride correspond to, for example, first and second insulation materials, respectively. The silicon nitride insulation film 40 and the silicon oxide insulation film 60 correspond to, for example, a fourth gate insulation film and a third gate insulation film, respectively.

One of characteristic features of the present embodiment is that the nitride silicon insulation film 40 is not in contact with the semiconductor substrate S, but is located in a region away from the semiconductor substrate S by at least a distance corresponding to half of the height of the charge storage layer FG, and the silicon oxide insulation film 60 is buried up to the height of the nitride silicon insulation film 40. The film thickness of the silicon nitride insulation film 40 is equal to or less than that of the inter-gate insulation film 20. In the present embodiment, the silicon nitride insulation film 40 is formed to cover a top face of the cap material 30.

Effects of the semiconductor memory device according to the present embodiment will now be described with reference to a comparative example. A semiconductor memory device shown in FIGS. 5A to 5D is an example of a non volatile semiconductor memory device according to a first comparative example.

In the semiconductor memory device shown in FIGS. 5A to 5D, a silicon oxide insulation material is buried between individual stacked gate structures to electrically isolate each stacked gate. In addition, a silicon insulation film 140 is formed on the top of the stacked gate structure to form a structure which prevents impurities such as hydrogen and metal elements from entering from the outside.

In the cell structure shown in FIGS. 5A to 5D, however, problems described hereafter are raised when the sizes of the element region AA and the element isolation region between the element regions AA are reduced for further miniaturization.

If the size of the space between the control gates CG is reduced and a high voltage (for example, 20 V) is applied to a control gate CG when giving and receiving charges, then a high electric field is applied between the selected control gate CG and the charge storage layer FG adjacent to the selected control gate CG, because the potential on the adjacent charge storage layer FG is approximately 4 V. Since the distance between them becomes several tens nm, the electric field amounts to 8 MV/cm level. Since there is the inter-gate insulation film 20 between the control gate CG and the charge storage layer FG disposed right under the control gate CG, insulation deterioration caused by application of the high electric field is suppressed. However, there is only a silicon oxide insulation film which isolates gates from each other, between a control gate CG and a charge storage layer FG disposed right under an adjacent stacked gate, resulting in high vulnerability against insulation deterioration. There is a risk of occurrence of a problem that it might become impossible to apply a high voltage to the control gate.

For recent large-capacity non volatile memories, the ultra-multi-level technique which increases the effective data quantity of bit unit by providing one memory cell with eight-value information or sixteen-value information is also used. In this case, it is necessary to individually provide each memory cell with a threshold voltage according to respective information quantity of each data. As the ultra-multi-level technique advances, therefore, it is necessary to apply a further high voltage (for example, 24 V) to the control gate CG and to conduct cell writing under a higher threshold voltage. In cell structures shown in FIGS. 5A to 5D, however, only the silicon oxide insulation film 60 which isolates the control gates CG from each other is formed between the charge storage layers FG located right under adjacent stacked gates. This results in a problem that it might become impossible to apply a high voltage because of insulation deterioration.

On the other hand, in the cell structure according to the first embodiment described above, the silicon nitride insulation film 40 formed of silicon nitride having a permittivity which is higher than that of the silicon oxide insulation material exists in a part which is in contact with the stacked gate structure. When a high voltage (for example, 20 V) is applied to the control gate CG in this structure, therefore, dielectric breakdown is prevented from being caused between the control gate CG and the charge storage layer FG located right under the adjacent control gate CG by the electric field alleviation effect in the silicon nitride insulation film 40.

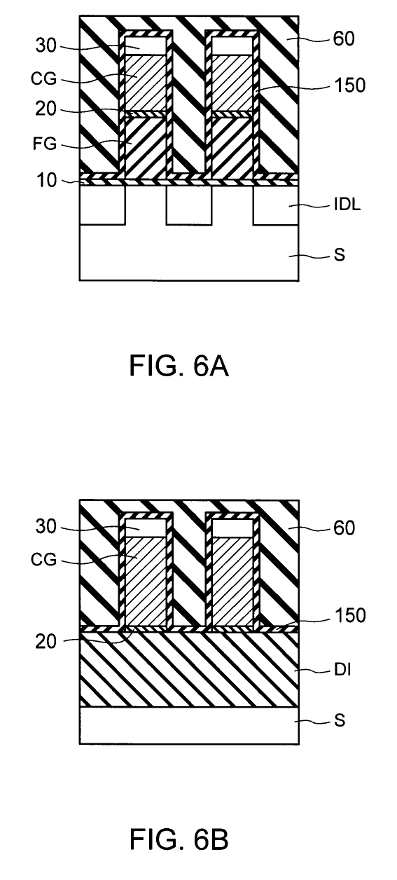

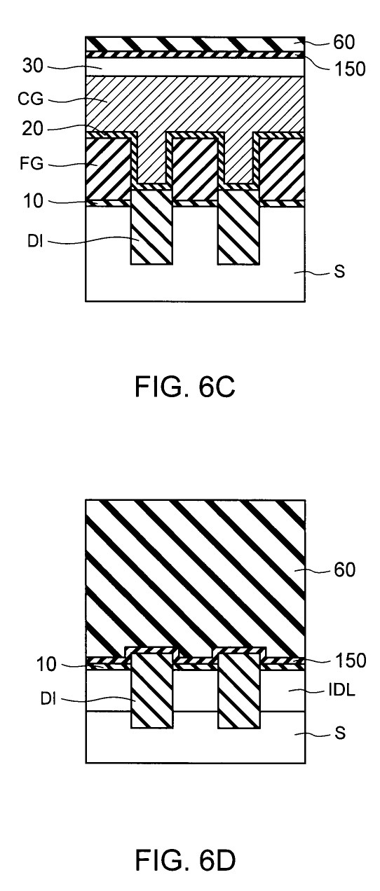

FIGS. 6A to 6D show an example of a non volatile semiconductor memory device according to a second comparative example. A silicon nitride insulation film 150 is formed to be in contact not only with side faces of the individual stacked gate structure but also with the substrate surface between those stacked gate structures and cover them. As a result, impurities such as hydrogen and metal elements are prevented from entering outside. In addition, a silicon oxide insulation material is buried between adjacent control gates CG and between adjacent charge storage layers FG via a silicon nitride insulation film 150 to conduct element isolation.

A feature of the cell in the present example will now be described. The silicon nitride insulation film 150 which is liable to capture electrons is inserted on the side walls of the stacked gate. Even if a high voltage is applied between the selected control gate CG and the charge storage layer FG located right under a control gate CG adjacent to the selected control gate CG and a leak current is generated because of insulation deterioration of the silicon oxide insulation film 60, therefore, the silicon nitride insulation film 150 suppresses it and consequently a high voltage can be applied.

In the cell structure of the present example, however, the silicon nitride insulation film 150 which is liable to capture electrons is in contact with the semiconductor substrate in a space part between the charge storage layers FG5. If charge giving and receiving are repeated between the charge storage layer FG and the semiconductor substrate S, therefore, partial charges are captured at an interface of the silicon nitride insulation film 150 or a trap level in the film on an n-type impurity diffusion layer IDL at an stacked gate end, and consequently the electron density at the surface of the n-type impurity diffusion layer IDL falls remarkably, resulting in a risk of occurrence of the problem that the cell channel current might be remarkably deteriorated. If the sizes of the gate width and the gate space are reduced in order to attain a higher density and a larger capacity of the memory, there is a possibility that the parasitic capacitance between adjacent charge storage layers FG might become unignorable and precise threshold control might become impossible due to interference between adjacent cells, because there is the silicon nitride insulation film 150 having a high relative permittivity between adjacent charge storage layers FG.

On the other hand, in the cell structure according to the first embodiment described above, although the silicon nitride insulation film 40 exists right above the semiconductor substrate in the space part between the charge storage layers FG, the silicon nitride insulation film 40 is remote from the semiconductor substrate S by a sufficiently large distance without being in contact with it. Even if the charge giving and receiving are repeated between the charge storage layer FG and the semiconductor substrate S, therefore, no charges are captured at the interface of the silicon nitride insulation film 40 or the capture level above the n-type impurity diffusion layer IDL at the stacked gate end does not occur. Therefore, there is raised no problem that the electron density at the surface of the n-type impurity diffusion layer IDL falls and the cell channel current is deteriorated. The silicon nitride insulation film 40 is buried up to only half of the height of the charge storage layer FG and its thickness is very thin. Therefore, the parasitic capacitance between adjacent charge storage layers can also be made very small. As a result, spread of threshold distribution can be sufficiently suppressed, and precise threshold control becomes possible.

### (3) Second Embodiment

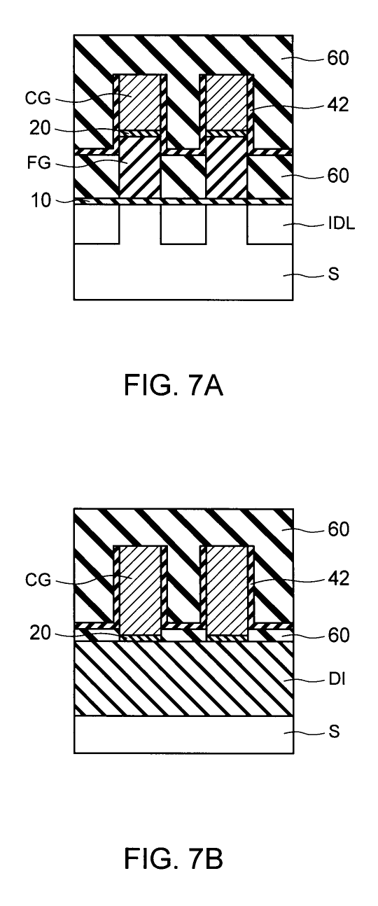

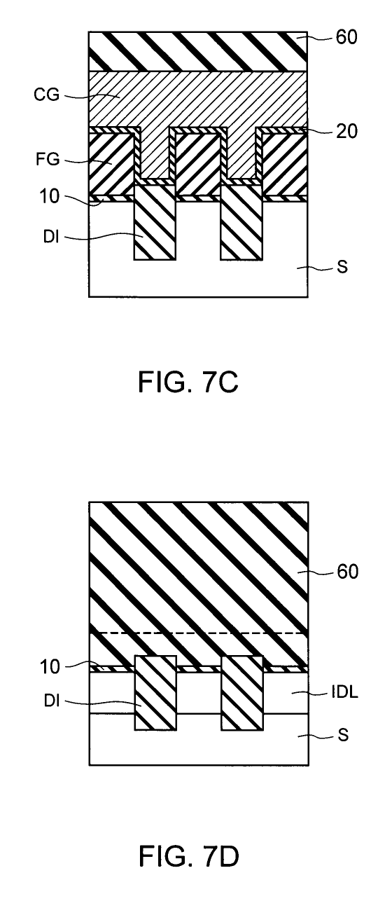

FIGS. 7A to 7D are sectional views schematically showing a memory structure of a non volatile semiconductor memory device according to a second embodiment of the present invention. The present embodiment is obtained by changing the arrangement of the silicon nitride insulation film and modifying the cell structure of the first embodiment described above. More specifically, a shape of a silicon nitride insulation film 42 is equivalent to a shape obtained by removing a part of the silicon nitride insulation film 40 which is located above the control gate CG as is shown in FIG. 4A, and by exposing the top face of the control gate CG. Such a shape can be implemented by forming a silicon nitride insulation film and then planarizing the top of the control gate by using a planarization process, for example, the Chemical Mechanical Polishing (CMP) technique. The remaining part of the memory structure in the present embodiment is substantially the same as that in the first embodiment described above. In the present embodiment, the silicon nitride insulation film 42 corresponds to, for example, the fourth gate insulation film.

The memory structure in the present embodiment is suitable for the case where, for example, a silicide material is formed on the top face of the control gate CG.

### (4) Third Embodiment

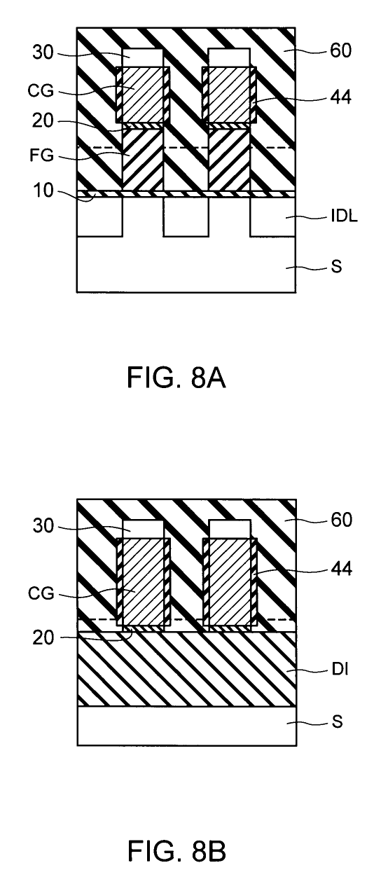

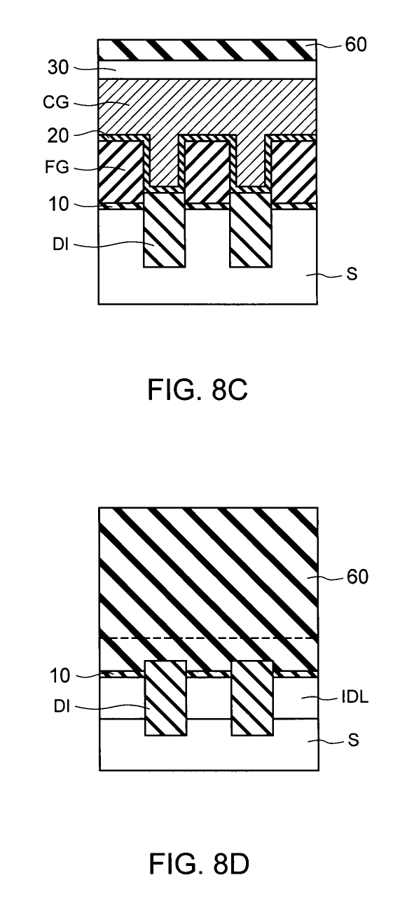

FIGS. 8A to 8D are sectional views schematically showing a memory structure of a non volatile semiconductor memory device according to a third embodiment of the present invention. A characteristic feature of the present embodiment is that a silicon nitride insulation film 44 is formed only on side walls of the control gate CG. If the material of the control gate CG is, for example, polycrystalline silicon, then such a shape can be implemented by using the selective growth technique or the thermal nitriding technique. The remaining part of the memory structure in the present embodiment is substantially the same as that in the first embodiment described above. In the present embodiment, the silicon nitride insulation film 44 corresponds to, for example, the fourth gate insulation film.

By modifying the arrangement of the silicon nitride insulation film in this way, effects similar to those of the first embodiment can be obtained regardless of the material of the control gate CG.

### (5) Fourth Embodiment

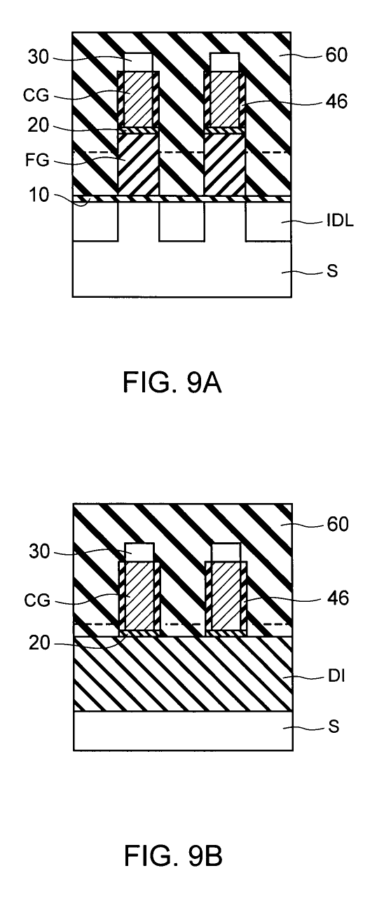

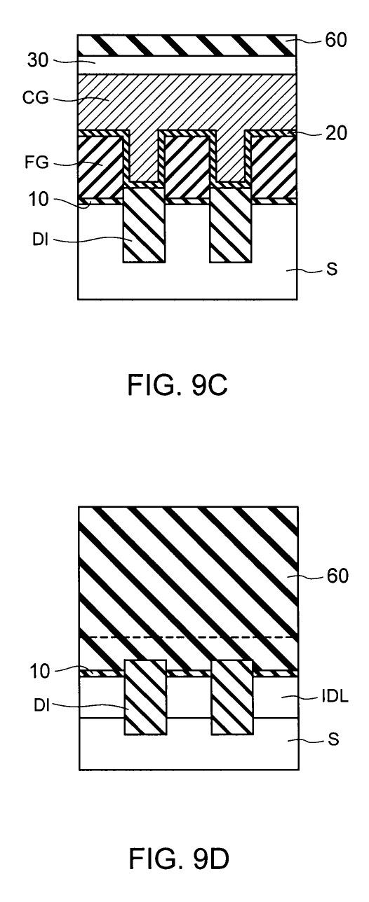

FIGS. 9A to 9D are sectional views schematically showing a memory structure of a non volatile semiconductor memory device according to a fourth embodiment of the present invention. A first characteristic feature of the present embodiment is that a silicon nitride insulation film 46 is formed only on side walls of the control gate CG and that no silicon nitride insulation materials are buried between the charge storage layers FG. Therefore, a silicon oxide insulation material is buried between the individual stacked gates. In addition, a second characteristic feature of the present embodiment is that the charge storage layer FG is subjected to vertical processing in a self-aligned manner to align the side walls of the charge storage layer FG located right under the control gate CG, with side walls of the silicon nitride insulation film 46. By such a vertical processing in a self-aligned manner, the side wall of the silicon nitride insulation film 46, the side wall of the inter-gate insulation film 20, and the side wall of the charge storage layer FG are substantially on the same plane along a vertical direction. Except these two points and a point that the stacked gate cap material 30 and the control gate CG are made thinner according to a film thickness of the silicon nitride insulation film 46, the remaining part of the memory structure in the present embodiment is substantially the same as that in the third embodiment described earlier. In the present embodiment, the silicon nitride insulation film corresponds to, for example, the fourth gate insulation film, and the vertical direction corresponds to, for example, a third direction. In addition, it is noted in the present invention that “substantially on the same plane” means that a minute asperity generated by the vertical processing is to be neglected.

According to such a structure in the present embodiment, the silicon nitride insulation film 46 exists on the side walls of the control gate CG and consequently effects similar to those in the first embodiment can be obtained. In addition, other excellent effects described in detail hereafter can also be brought about.

Specifically, in general, if the size of the element region is reduced, the gate capacitance of the memory cell itself also becomes small, whereas the parasitic between adjacent charge storage layers FG increases because the size of the space between elements is reduced. As a result, interference between adjacent cells increases and the threshold control becomes very difficult. Thus, the threshold distribution after data writing spreads. This brings about a problem that multi-leveling and ultra-multi-leveling of storage bits such as four values, eight values and sixteen values are obstructed. It is necessary to increase the gate capacitance to solve this problem. Therefore, it becomes important to form the charge storage layer FG thick, increase the height of side walls of the charge storage layer FG, and increase the gate capacitance between the charge storage layer FG and the control gate CG. If the charge storage layer FG is made thick, however, the processing margin of the stacked gate structure becomes remarkably narrow when reducing the sizes of the gate width and the gate space. In general, therefore, it can be said to be advisable to lower the height of the element isolation insulation film DI and widen the opposition area between the charge storage layer FG and the control gate CG. However, if the height of the element isolation insulation film DI is lowered, the control gate CG located over the element isolation insulation film DI gets closer to the element region on side ends of the control gate CG. If a high voltage (for example, 20 V) is applied to the control gate CG at the time of charge giving and receiving, a high electric field is thus applied between the control gate CG and the element region on the side ends of the control gate CG. Since the distance between them becomes several tens nm, the intensity of the electric field mounts to the level of 10 MV/cm. Since there is the inter-gate insulation film 20 between the control gate CG and the element region at the end of the element isolation region located right under the control gate CG, insulation deterioration caused by application of a high electric field, and electron trapping at the interface are suppressed. On the other hand, since only the silicon oxide insulation film isolating the gates from each other is formed on the element region beside the control gate in the typical memory cell structure, strength against insulation deterioration and electron trapping is very weak, and there is a possibility that the cell characteristics may be deteriorated if the charge giving and receiving is repeated.

On the other hand, according to the memory cell structure in the present embodiment, the silicon nitride insulation film 46 formed on the side wall of the control gate CG suppresses insulation deterioration between the control gate CG and the element region AA. Therefore, it becomes possible to suppress the above-described problem. The memory structure shown in FIGS. 9A to 9D can also be formed by changing a part of the vertical gate processing procedure. For example, the control gate CG and the inter-gate insulation film 20 is subjected to vertical processing, and then a silicon nitride insulation film having a film thickness which is equal to or less than the film thickness of the inter-gate insulation film 20 is formed. Subsequently, the silicon nitride insulation film is removed from the top face of the control gate CG by using the dry etching technique, and the silicon nitride insulation film 46 is formed only on side walls of the control gate CG. Then, the charge storage layer FG located, for example, the polycrystalline silicon material right under the control gate CG is subjected to vertical processing by using gas which has a high selection ratio with respect to the silicon nitride material. As a result, the desired stacked gate structure can be formed.

### (6) Fifth Embodiment

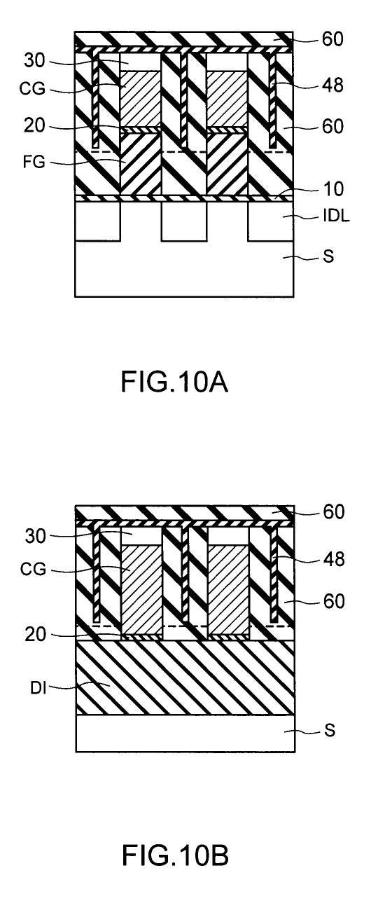

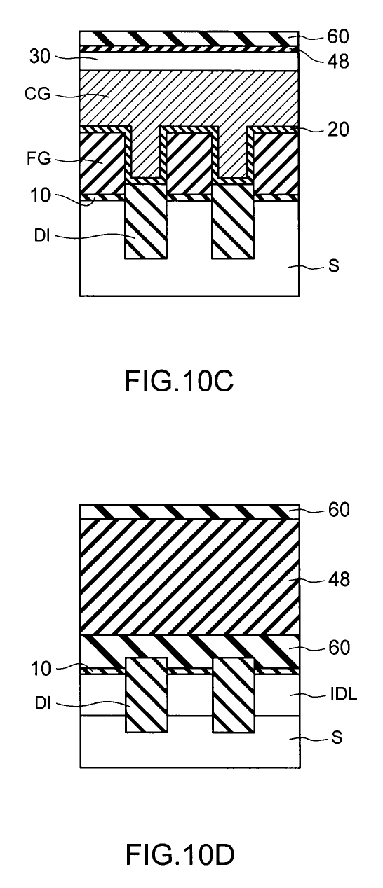

FIGS. 10A to 10D are sectional views schematically showing a memory structure of a non volatile semiconductor memory device according to a fifth embodiment of the present invention. A characteristic feature of the present embodiment is that a silicon nitride insulation film 48 is not disposed to be in contact with the control gate CG, but is disposed in the vicinity of the center of the space between adjacent control gates CG. Such structure of the present embodiment can be implemented by, for example, first filling the space between the stacked gates with a silicon oxide insulation material to form the silicon oxide insulation film 60 and burying a silicon nitride insulation material in the gap that remains after the filling process with the silicon oxide insulation material. Also in the structure shown in FIGS. 10A to 10D, it is possible to remove the silicon nitride insulation film from the top part of the control gate CG in a planarization process in the same way as the second embodiment described earlier. In the present embodiment, silicon oxide and silicon nitride correspond to, for example, the first and second insulation materials, respectively, and the silicon oxide insulation material 60 and the silicon nitride insulation film 48 correspond to, for example, the third gate insulation film and the fourth gate insulation film.

In the present embodiment, the silicon nitride insulation film 48 is not disposed on the gate structure side, but is inserted in the intermediate part of the inter-gate space. Therefore, the electric field alleviation effect in the embodiments described above cannot be anticipated. On the other hand, since the silicon nitride insulation film 48 also has a feature that it is liable to capture electrons therein, it is possible to anticipate the effect that a leak current injected from the control gate CG is alleviated and the insulation deterioration is suppressed. Incidentally, which of the method of alleviating the inter-gate electric field to suppress the insulation deterioration described earlier with reference to FIG. 1 and the method in the present embodiment is effective depends upon the stacked gate structure and the kind of the insulation film. Therefore, it is to be noted that the effects of them cannot be compared with each other unconditionally.

### (7) Sixth Embodiment

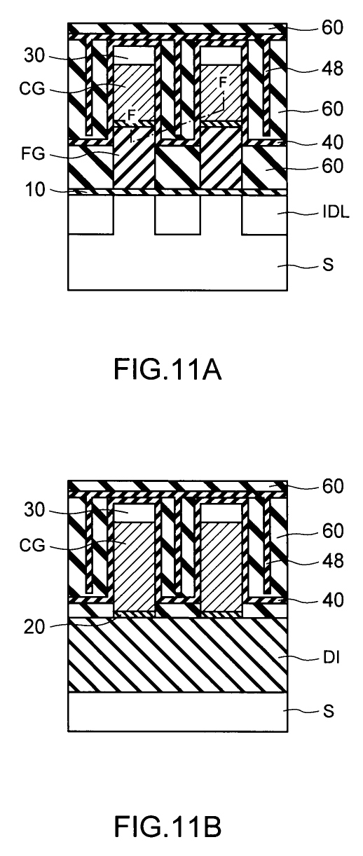

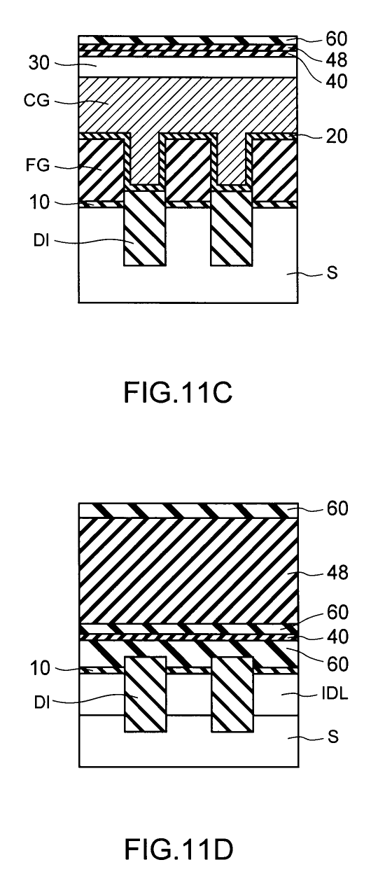

FIGS. 11A to 11D are sectional views schematically showing a memory structure of a non volatile semiconductor memory device according to a sixth embodiment of the present invention. A characteristic feature of the present embodiment is that both the electric field alleviation effect according to the first to fourth embodiments and the electron capture effect according to the fifth embodiment described above can be obtained simultaneously. By paying attention to a cut line F-F in FIG. 11A, it is appreciated that the memory structure in the present embodiment has an inter-gate insulation film structure having five layers. More specifically, the silicon nitride insulation film 40 is disposed in contact with adjacent control gates CG and the silicon nitride insulation material 48 is disposed in an intermediate part between the control gates CG. In addition, a silicon oxide insulation film 60 is inserted between them. As a result, it can be anticipated that both the electric field alleviation effect on the gate structure side and the leak current alleviation effect in the inter-gate intermediate part can be obtained simultaneously. In the present embodiment, silicon oxide corresponds to, for example, the first insulation material and silicon nitride corresponds to, for example, second and third insulation materials. The silicon oxide insulation film 60 corresponds to, for example, the third gate insulation film, and the silicon nitride insulation films 40 and 48 correspond to, for example, the fourth gate insulation film and a fifth gate insulation film, respectively.

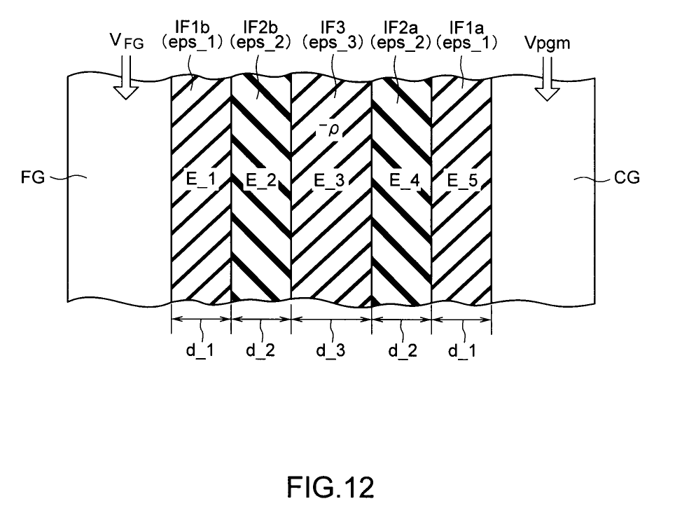

FIG. 12 schematically shows a solving method of alleviating the inter-gate electric field in the memory structure shown in FIGS. 11A to 11D and suppressing the insulation deterioration. More specifically, relations among electric fields in respective films in a structure in which mutually adjacent stacked gate structures are disposed on the right side and the left side of the drawing and an inter-gate insulation film having a five-layer structure composed of, for example, insulation materials of three kinds is disposed between gates are shown on the assumption that the adjacent control gates CG are parallel plates. In FIG. 12, the control gate CG to which the write voltage (Vpgm) is applied is shown on the right side of the drawing, whereas the charge storage layer FG located right under the control gate CG to which the write preventing intermediate voltage (Vpass) is applied is shown on the left side of the drawing. The inter-gate insulation films IF1a and IF1b which are in contact with the control gate CG and the charge storage layer FG are formed of the insulation material A of the same kind. The relative permittivity of the insulation material A is denoted by eps_{—}1, its film thickness is denoted by d_{—}1, and the electric field strengths applied to the material A are denoted by E_{—}5 and E_{—}1. Inter-gate insulation films IF2a and IF2b formed of the insulation material B are inserted between the inter-gate insulation films IF1a and IF1b. The relative permittivity of the insulation material B is denoted by eps_{—}2, its film thickness is denoted by d_{—}2, and the electric field strengths applied to the material B are denoted by E_{—}4 and E_{—}2. In addition, an inter-gate insulation film IF3 formed of an insulation material C is inserted between the inter-gate insulation films IF2a and IF2b. The relative permittivity of the insulation material C is denoted by eps_{—}3, its film thickness is denoted by d_{—}3, and the electric field strength applied to the material C is denoted by E_{—}3. The permittivity of the vacuum is denoted by eps_{—}0. It is supposed that negative charges of a volume density p are captured in a position of x in the inter-gate insulation film IF3.

The electric field strength E_i (i=1, 2, 3, 4, 5) in each insulation film can be represented as

E_{—}1=σ/eps_{—}1 [Expression 3]

E_{—}2=σ/eps_{—}2 [Expression 4]

E_{—}3=σ/eps_{—}3+((ρ/eps_{—}0)/eps_{—}3) (x−d_{—}1−d_{—}2) [Expression 5]

E_{—}4=(σ+(ρ/eps_{—}0)*d_{—}3)/eps_{—}2 [Expression 6]

E_{—}5=(σ+(ρ/eps_{—}0)*d_{—}3)/eps_{—}1 [Expression 7]

### Where

σ=K*[V−(ρ/eps_{—}0)*d_{—}3*(0.5*d_{—}3/eps_{—}3+d_{—}2/ eps_{—}2+d_{—}1/eps_{—}1)] [Expression 8]

K=1/(2*d_{—}1/ eps_{—}1+2*d_{—}2/eps_{—}2+d_{—}3/eps_3) [Expression 9]

If negative charges are captured in the inter-gate insulation film IF3, then the electric field between the inter-gate insulation film IF3 and the charge storage layer FG located right under the control gate CG to which the write preventing intermediate voltage Vpass is applied can be alleviated. Even in the case where a leak current flows between adjacent gate structures, electrons in the leak current are captured in the inter-gate insulation film IF3 and the electric field is further alleviated, and consequently negative feedback which eventually suppresses the leak current is exercised, and it becomes possible to suppress the insulation deterioration. Supposing that the inter-gate insulation films IF1a and IF1b of the first layer are, for example, silicon nitride films (eps_{—}1=7.5, d_{—}1=2 nm), the inter-gate insulation films IF2a and IF2b of the second layer are, for example, silicon oxide films (eps_{—}2=3.9, d_{—}2=2 nm), the inter-gate insulation film IF3 of the third layer is, for example, silicon nitride film (eps_{—}3=7.5, d_{—}1=2 nm), a potential VFG on the charge storage layer FG located right under the control gate CG to which the write preventing intermediate voltage Vpass is applied is 4 V, and the dielectric breakdown voltage is 10 MV/cm for convenience of explanation, the voltage which can be applied between adjacent gate structures becomes 17.7 V at maximum. If negative charges of 1×10²⁰ cm⁻³ are disposed in the third layer, however, the voltage which can be applied is improved to 20.0 V.

### (8) Rest

Heretofore, some of embodiments of the present invention have been described. However, the present invention is never limited to those embodiments. It is a matter of course that various modifications of the present invention can be applied within the scope thereof. For example, in the above described embodiments, the case where the fourth gate insulation film formed to be in contact with the gate structure is only a single layer of the silicon nitride film 40, 42, 44 or 46 has been described. However, the present invention is not limited to this, but the fourth gate insulation film may be formed of a multi-layer insulation film including an insulation film other than the silicon nitride film.

What is claimed is:

1. A non volatile semiconductor memory device comprising:
a semiconductor substrate which comprises a plurality of element regions extending in a first direction;
a plurality of gate structures configured to extend in a second direction intersecting the first direction, each of the gate structures comprising a charge storage layer provided over the semiconductor substrate via a first gate insulation film, a second gate insulation film on the charge storage layer, and a control gate on the second gate insulation film;
a plurality of element isolation insulation films provided selectively on a surface of the semiconductor substrate to define the element regions and electrically isolate the element regions;
a plurality of impurity diffusion layers provided in the element regions so as to sandwich a surface layer of the semiconductor substrate located right under the gate structures therebetween;
a third gate insulation film of a first insulation material located between the gate structures; and
a fourth gate insulation film of a second insulation material which is different from the first insulation material configured to be in contact with side walls of the gate structures,
wherein a bottom face of the fourth gate insulation film is located so as to be remote from a surface of the semiconductor substrate by a distance equal to at least half of a height of the charge storage layer.

2. The non volatile semiconductor memory device of claim 1, wherein the second insulation material has a permittivity which is higher than that of the first insulation material.

3. The non volatile semiconductor memory device of claim 1, wherein the fourth gate insulation film has a film thickness which is equal to or less than that of the second gate insulation film.

4. The non volatile semiconductor memory device of claim 1, wherein a top of the gate structure is covered by the fourth gate insulation film.

5. The non volatile semiconductor memory device of claim 1, wherein a top of the gate structure is covered by the third gate insulation film.

6. The non volatile semiconductor memory device of claim 1, wherein the fourth gate insulation film comprises a silicon nitride film.

7. The non volatile semiconductor memory device of claim 1, wherein the fourth gate insulation film comprises a multilayer insulation film comprising a silicon nitride film.

8. The non volatile semiconductor memory device of claim 1, wherein the fourth gate insulation film is in contact with only side walls of the control gate.

9. The non volatile semiconductor memory device of claim 8 wherein side walls of the fourth gate insulation film, the second gate insulation film, and the charge storage layer along a third direction are substantially on the same plane, the third direction being orthogonal to the first and second directions.

10. A non volatile semiconductor memory device comprising:
a semiconductor substrate which comprises a plurality of element regions extending in a first direction;
a plurality of gate structures configured to extend in a second direction intersecting the first direction, each of the gate structures comprising a charge storage layer provided over the semiconductor substrate via a first gate insulation film, a second gate insulation film on the charge storage layer, and a control gate on the second gate insulation film;
a plurality of element isolation insulation films provided selectively on a surface of the semiconductor substrate to define the element regions and electrically isolate the element regions;
a plurality of impurity diffusion layers provided in the element regions so as to sandwich a surface layer of the semiconductor substrate located right under the gate structures therebetween;
a third gate insulation film of a first insulation material located between the gate structures; and
a fourth gate insulation film of a second insulation material having a permittivity which is lower than that of the first insulation material in contact with side walls of the gate structure and the semiconductor substrate between the gate structures.

11. The non volatile semiconductor memory device of claim 10, wherein a top of the gate structure is covered by the third gate insulation film.

12. The non volatile semiconductor memory device of claim 10, wherein the third gate insulation film comprises a silicon nitride film.

13. The non volatile semiconductor memory device of claim 10, wherein the third gate insulation film comprises a multilayer insulation film comprising a silicon nitride film.

14. A non volatile semiconductor memory device comprising:
a semiconductor substrate which comprises a plurality of element regions extending in a first direction;
a plurality of gate structures configured to extend in a second direction intersecting the first direction, each of the gate structures comprising a charge storage layer provided over the semiconductor substrate via a first gate insulation film, a second gate insulation film on the charge storage layer, and a control gate on the second gate insulation film;
a plurality of element isolation insulation films provided selectively on a surface of the semiconductor substrate to define the element regions and electrically isolate the element regions;
a plurality of impurity diffusion layers provided in the element regions so as to sandwich a surface layer of the semiconductor substrate located right under the gate structures therebetween;
a third gate insulation film of a first insulation material located between the gate structures; and
a fourth gate insulation film of a second insulation material which is different from the first insulation material in contact with side walls of the gate structure; and
a fifth gate insulation film of a third insulation material which is different from the first insulation material, located in the third gate insulation film,
wherein the second and third insulation materials are higher in permittivity than the first insulation material.

15. The non volatile semiconductor memory device of claim 14, wherein the fourth gate insulation film comprises a silicon nitride film.

16. The non volatile semiconductor memory device of claim 14, wherein the fourth gate insulation film comprises a multilayer insulation film comprising a silicon nitride film.
